(19) United States
(12) Patent Application Publication
(10) Pub. No.: US 2026/0247772 A1
(43) Pub. Date: Aug. 20, 2026

(54) MIXED LIGHT RGB STACKED STRUCTURE AND PACKAGING METHOD THEREOF

(71) Applicant: HEFEI SMAT TECHNOLOGY CO. LTD., HEFEI CITY (CN)

(72) Inventor: Xiaochun TAN, HEFEI CITY (CN)

(21) Appl. No.: 19/460,463

(22) Filed: Jan. 27, 2026

(30) Foreign Application Priority Data
Feb. 18, 2025 (CN) 202510173667.X

(51) Int. Cl. H10H 29/01; H10H 29/24; H10H 29/85; H10H 29/853; H10H 29/856

(52) U.S. Cl. CPC H10H 29/0364; H10H 29/0362; H10H 29/24; H10H 29/853; H10H 29/856; H10H 29/857

(57) ABSTRACT

A mixed-light RGB stacked structure and a packaging method thereof are provided. The packaging method comprise: mounting a chip; drilling a encapsulation surface exposing a front surface of the chip until a top surface of a metal block encapsulated in the chip is exposed; extending electroplated metal in a hole and on the encapsulation surface; encapsulating the electroplated metal; drilling the encapsulation surface, electroplating wire to lead the other electrodes on the front surface of the chip out to the top side, encapsulating the wire; mounting a light-emitting unit group into a groove on a top of the encapsulation surface exposing a top of the wire, electrically connecting the light-emitting unit group to the wire. An overall size of the structure is reduced, and an inner wall of the groove reflects and converges light of the three primary colors lamp beads of the light-emitting unit group, achieving good color-mixing effect.

### CROSS-REFERENCE TO RELATED APPLICATIONS

This present disclosure claims priority to a Chinese patent application No. 202510173667.X, filed on February 18, 2025, and entitled "mixed light RGB stacked structure and packaging method thereof", the entire contents of which are incorporated herein by reference, including the specification, claims, drawings and abstract.

### FIELD OF TECHNOLOGY

The present disclosure relates to a field of RGB packaging technology, particularly, to a mixed light RGB stacked structure and a packaging method thereof.

### BACKGROUND

With the development of integrated circuits and devices towards miniaturization, semiconductor devices, as one of the core electronics of integrated circuits, also show the development requirements of high integration, miniaturization, high performance, and low cost. In this field, RGB LEDs and white LEDs both can achieve white light effects. The difference is that white LEDs directly present white monochromatic light, while RGB LEDs are formed by mixing red, green and blue three primary colors of light. Therefore, RGB lights are formed by the intersection of the three primary colors. RGB lights can adjust the intensity of these three colors separately to achieve a mixed light effect, thereby realizing a very rich range of lighting effects. RGB lights are widely used in stage lighting, billboards, building exteriors, and other occasions.

The intensity of the three primary colors of light during mixing is controlled and adjusted by an IC chip electrically connected to the RGB. The control chip is the core of the integrated circuit used to control the RGB lights. In the prior art, when the RGB three primary color lights are electrically connected to the control chip, the RGB packaging is completed as a package body and then electrically connected to the chip through a wiring layer, and then packaged into an integral body with packaging material, resulting in a larger overall packaging size and poor mixed light effect of the RGB lights.

### SUMMARY OF THE DISCLOSURE

To solve the above-mentioned problems in the prior art, the present disclosure provides a mixed light RGB stacked structure and a packaging method thereof.

To achieve the above purpose, the present disclosure provides a mixed light RGB stacked structure and a packaging method thereof, including following steps of:

chip mounting: mounting the chip on a substrate in which a metal block is encapsulated, encapsulating the chip, and grinding an encapsulation surface to expose a front surface of the chip;

electrically leading-out at a bottom side: drilling the encapsulation surface that exposes the front surface of the chip until a top surface of the metal block is exposed; extending electroplated metal in a hole and on the encapsulation surface, so that part of electrodes on the front surface of the chip are electrically conducted through the electroplated metal to the metal block and then led out to the bottom side; and encapsulating the electroplated metal;

electrically leading-out at a top side: drilling the encapsulation surface until the other electrodes on the front surface of the chip are exposed, electroplating wire to lead the other electrodes on the front surface of the chip out to the top side, and encapsulating the wire; and

light-emitting unit group mounting: etching a groove on a top of the encapsulation surface to expose a top of the wire; mounting the light-emitting unit group into the groove, and connecting the light-emitting unit group to the wire, so that the chip and the light-emitting unit group are electrically connected; stripping the substrate; and forming a package body.

Further, in the step of chip mounting, the substrate is provided, the metal block is electroplated on the substrate, the metal block is set at equal height; the metal block is encapsulated on the substrate; the top of the encapsulation surface is grinded to expose the top surface of the metal block; and the chip is mounted on the encapsulation surface, a back side of the chip faces the substrate.

Further, in the step of electrically leading-out at the bottom side, a metal post is electroplated in the hole, and a metal routing layer is electroplated on the encapsulation surface, wherein the routing layer connects the post and the part of electrodes on the front surface of the chip, so that the part of electrodes on the front surface of the chip are electrically conducted through the routing layer and the post to the metal block and then led out to the bottom surface.

Further, in the step of electrically leading-out at the top side, the wire comprises metal electroplated in the hole and metal extended on the encapsulation surface, and two parts of metal are electroplated connected as a whole.

Further, in the step of light-emitting unit group mounting, the groove is formed by laser etching and is located above the chip.

Further, in the step of light-emitting unit group mounting, the light-emitting unit group comprises red, green and blue three primary colors lamp beads, the lamp beads being respectively mounted at a bottom of the groove and electrically connected to the wire.

Further, in the step of light-emitting unit group mounting, a transparent encapsulant layer is filled in the groove so that a top side of the package body is flat.

A mixed light RGB stacked structure is provided and comprises a package body, wherein the package body encapsulates:

a chip, part of electrodes on a front surface of the chip being electrically conducted to a bottom side of the package body through an electroplated routing layer, a post and a metal block, a bottom surface of the metal block being exposed and flush with from the bottom side of the package body;

a wire, the other electrodes on the front surface of the chip being led out to a top side of the package body through electroplated wire;

a groove, etched on the top side of the package body at a corresponding position, a top of the wire being exposed within the groove;

a light-emitting unit group, mounted in the groove and electrically connected to the top of the wire, thereby the chip and the light-emitting unit group are electrically connected.

Further, after the metal block is electroplated and encapsulated, their top surfaces are exposed by grinding, the chip is mounted on the encapsulation surface and encapsulated, and then the front surface of the chip is exposed by grinding.

Further, the encapsulation surface is drilled to expose a top surface of the metal block, a metal post is electroplated in the hole, and a routing layer is electroplated on the encapsulation surface to connect the post and the part of electrodes on the front surface of the chip.

Further, the wire comprises metal electroplated in the hole and metal extended on the encapsulation surface, and two parts of metal are electroplated connected as a whole.

Further, the groove is formed by laser etching and is located above the chip.

Further, the light-emitting unit group comprises red, green and blue three primary colors lamp beads, the lamp beads being respectively mounted at a bottom of the groove and electrically connected to the wire.

Further, a transparent encapsulant layer is filled in the groove so that a top side of the package body is flat.

The present disclosure, by mounting the chip in a face-up manner, then forming a groove on the top surface of the encapsulation and mounting the light-emitting unit group, achieves electrical control of the light-emitting unit group by the chip. The entire process is simple, the size is reduced, the cost is lowered, and the inner wall of the groove formed in the encapsulation body has a reflective and converging effect on the three primary colors lights of the light-emitting unit group, resulting in a good mixed light effect.

### BRIEF DESCRIPTION OF THE DRAWINGS

FIGS. 1-5 are sectional views of a step of chip mounting in a packaging method of a mixed light RGB stacked structure according to the present disclosure;

FIGS. 6-8 are sectional views of a step of electrical leading-out at a bottom side in a packaging method of a mixed light RGB stacked structure according to the present disclosure;

FIGS. 9-11 are sectional views of a step of electrical leading-out at a top side in a packaging method of a mixed light RGB stacked structure according to the present disclosure;

FIGS. 12-15 are sectional views of a step of light-emitting unit group mounting in a packaging method of a mixed light RGB stacked structure according to the present disclosure;

FIG. 16 is a sectional view of a mixed light RGB stacked structure according to the present disclosure;

FIG. 17 is another sectional view of a mixed light RGB stacked structure according to the present disclosure.

In the drawings: 1. Package body; 2. Chip; 3. Wire; 4. Groove; 5. Light-emitting unit group; 6. Metal block; 7. Post; 8. Routing layer.

### DETAILED DESCRIPTION OF THE DISCLOSURE

Below is a detailed description of the mixed light RGB stacked structure and its packaging method proposed by the present disclosure, in combination with specific embodiments. The examples of the embodiments are shown in the drawings, where the same or similar reference numerals throughout indicate the same or similar components or components having the same or similar functions.

The directional terms mentioned in the present disclosure, such as up, down, left, right, front, back, inside, outside, front side, back side, side, etc., are merely referenced to the direction of the drawings. The implementation methods described below with reference to the drawings and the directional terms used are exemplary, only for explaining the present disclosure, and should not be understood as a limitation to the present disclosure. In addition, the various specific processes and materials provided by the present disclosure are examples that ordinary technicians in the field can be aware of other processes and/or other materials can be used.

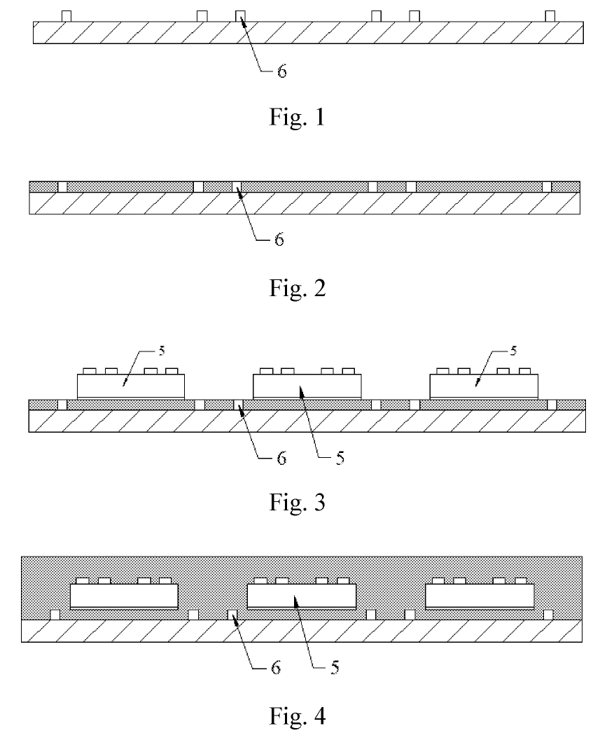

To better understand the purpose, structure, and function of the present disclosure, the mixed light RGB stacked structure and its packaging method proposed by the present disclosure will be further described in detail below in combination with FIGS. 1-15. The method includes the following steps:

Chip 2 mounting: mounting a chip 2 on a substrate in which a metal block 6 is encapsulated, encapsulating the chip 2, and grinding the encapsulation surface to expose the front surface of the chip 2;

Electrical lead-out at a bottom side: drilling the encapsulation surface that exposes the front surface of the chip 2 until the top surface of the metal block 6 is exposed, and extending electroplated metal in the hole and on the encapsulation surface, so that part of the electrodes on the front surface of the chip 2 are electrically conducted through the electroplated metal to the metal block 6 and then led out to the bottom side, and encapsulating the electroplated metal;

Electrical lead-out at a top side: drilling the encapsulation surface until the other electrodes on the front surface of the chip 2 are exposed, electroplating the wire 3 to lead the other electrodes on the front surface of the chip 2 out to the top side, and encapsulating the wire 3;

Light-emitting unit group 5 mounting: etching a groove 4 on the top of the encapsulation surface to expose the top of the wire 3, mounting the light-emitting unit group 5 into the groove 4 and connecting it to the wire 3, thereby achieving electrical connection between the chip 2 and the light-emitting unit group 5, stripping the substrate, and forming a package body 1.

Among them, as shown in FIGS. 1-5, in the chip 2 mounting step, a substrate is provided, which is made of commonly used materials in this field, such as a resin board or other materials. According to a surface area of the substrate, a plurality of metal blocks 7 are uniformly electroplated at the corresponding positions on the substrate (as shown in FIG. 1), and heights of the metal blocks 7 that are electroplated are the same. After electroplating, an encapsulation material is used on the substrate to encapsulate the metal blocks 6, and then a top surface of the encapsulation is grinded by mechanical grinding to expose top surfaces of all metal blocks 6 (as shown in FIG. 2).

Then, the chip 2 is mounted at the corresponding position on a grinded encapsulation surface, with a back surface (non-functional side) of the chip 2 mounted on the packaging surface facing the substrate and a front surface (functional side) facing up. The front surface of the chip 2 is equipped with a Bump (solder ball) conductive electrode structure. According to the surface area of the substrate, the number of chips 2 to be placed can be set. In the present disclosure, three chips 2 are placed as an example, and the chips 2 are respectively mounted at the corresponding positions of the metal blocks 6. The back side of the chip 2 is attached to the encapsulation surface with adhesive (as shown in FIG. 3). Then, the encapsulation material continues to be used on the encapsulation surface that exposes the top surface of the metal block 6 to completely encapsulate the chip 2 (as shown in FIG. 4). Similarly, the top surface of the encapsulation is grind by mechanical grinding until all the front electrodes of the chip 2 are exposed (as shown in FIG. 5).

The chip 2 can be an RGB control chip 2, which is the core of the integrated circuit specifically used to control RGB lights. It can regulate the brightness of each of the three primary color channels through voltage or digital signals, thereby achieving precise control of RGB lights. Its working principle is to adjust the brightness of RGB lights by changing the duty cycle of the PWM signal (pulse width modulation). Since this type of chip 2 usually contains multiple PWM controllers, it can be used to control the brightness of the red, green, and blue channels separately. In addition, it also includes a color correction circuit to correct the color imbalance between RGB channels and ensure the accuracy of the output color. It usually has a wide input voltage range and high current output capability, making it suitable for various types of RGB light applications. At the same time, it also has multiple protection functions, such as over-temperature protection, over-current protection, and short-circuit protection, to ensure the reliability and safety of LED lights. The chip 2 used in the present disclosure is a common type in this field.

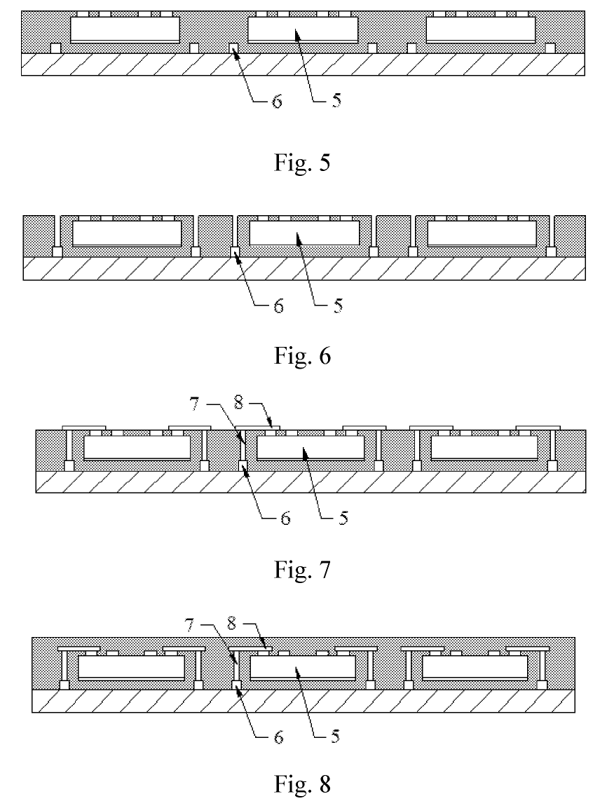

Among them, as shown in FIGS. 6-8, in the step of electrical leading-out at a bottom side, holes are drilled at the positions corresponding to the metal blocks 6 on the horizontal encapsulation surface that exposes the front surface of the chip 2 by laser or other etching methods to remove the encapsulation material above the metal block 6, exposing the top surface of the metal block 6 at the bottom of the hole (as shown in FIG. 6). The electroplating process continues, with the electroplating solution first penetrating into the hole to electroplate and fill it, forming a metal post 7. Then, the electroplating continues on the encapsulation surface to form a routing layer 8 along the surface (as shown in FIG. 7). The routing layer 8 covers the top of the post 7, and the post 7 and the routing layer 8 are electroplated and connected as a whole. The post 7 and the metal block 6 are also electroplated and connected as a whole. One end of the routing layer 8 extends along the encapsulation surface to cover part of the electrodes of the chip 2 and is electroplated and connected to that electrode of the chip 2 as a whole, realizing the electrical connection from part of the electrodes of the chip 2 to the metal block 6. The electrical properties of part of the electrodes on the front surface of the chip 2 are conducted through the electroplated metal to the metal block 6 and then led out to the bottom surface of the encapsulation material. Then, the encapsulation material continues to be used on the encapsulation surface formed in the chip 2 mounting step to encapsulate the electroplated metal routing layer 8 and post 7 (as shown in FIG. 8). According to the height dimension design of the entire product, the optimal encapsulation thickness is set here, and the encapsulation surface is flat and smooth after encapsulation.

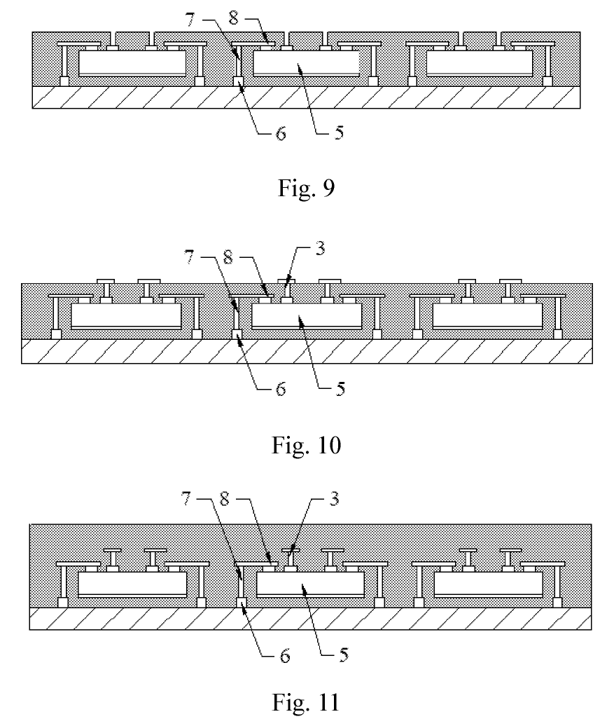

Among them, as shown in FIGS. 9-11, in the step of electrical leading-out at a top side, holes are drilled at the corresponding positions on the encapsulation surface formed in the step of electrical leading-out at a bottom side by laser or other etching methods. The corresponding position refers to the other electrodes on the chip 2 except for the part of the electrodes electrically connected to the metal block 6 in the step of electrical leading-out at a bottom side. The drawings are sectional views, only showing the electrodes of the chip 2 that are not blocked. The number of electrodes is set according to the electrical connection situation of the chip 2. Since the remaining other electrodes need to be electrically connected to the light-emitting unit group 5 to realize the electrical control of the light-emitting unit group 5 by the chip 2, and each group of the light-emitting unit group 5 has red, green, and blue three primary colors lamp beads, the remaining other electrodes should be set to three. The encapsulation material corresponding to part of the electrodes of the chip 2 is removed to expose the other electrodes of the chip 2 at the bottom of the hole (as shown in FIG. 9). The electroplating process continues, with the electroplating solution first penetrating into the hole to electroplate and fill it with metal. Then, the electroplating continues on the encapsulation surface to plate metal along the surface. The two parts of metal are electroplated and connected as a whole to form a wire 3 (as shown in FIG. 10). The wire 3 leads the electrical properties of the other electrodes on the front surface of the chip 2 out to the top surface of the encapsulation material. The bottom surface refers to the lowest surface of all the encapsulation materials that make up the encapsulation, that is, the surface close to the substrate in the drawings. The top surface refers to the top surface of all the encapsulation materials that make up the encapsulation, that is, the opposite surface of the bottom surface of the encapsulation material. The electrodes of the chip 2 are led out of the encapsulation material in two opposite directions through the drilling, electroplating, and encapsulation process. The encapsulation material continues to be used on the encapsulation surface formed in the step of electrical leading-out at a bottom side to completely encapsulate the wire 3 (as shown in FIG. 11). According to the height dimension design of the entire product and the height dimension of the red, green, and blue three primary colors light-emitting unit group 5, the optimal encapsulation thickness is set here, and the encapsulation surface is flat and smooth after encapsulation.

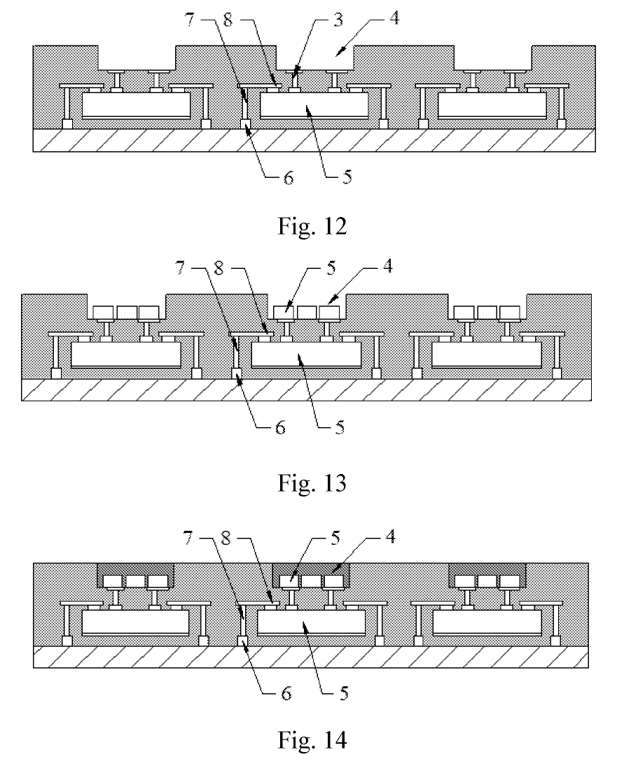

Among them, as shown in FIGS. 12-15, in the step of light-emitting unit group 5 mounting, a groove 4 is etched at the corresponding position above the chip 2 on the encapsulation surface formed in the step of electrical leading-out at a top side. The groove 4 is formed by laser etching, and the top surface of the wire 3 is exposed in the groove 4 (as shown in FIG. 12). The light -emitting unit group is mounted into the groove 4 (as shown in FIG. 13). Each group of the light-emitting unit group 5 consists of red, green, and blue three primary colors lamp beads. The three primary colors lamp beads of the light-emitting unit group 5 are electrically connected to the wire 3 respectively, realizing the separate electrical control of each three primary colors lamp bead in the light-emitting unit group 5 by the chip 2. The chip 2 is the core of the integrated circuit specifically used to control RGB lights and can regulate the brightness of each three primary colors lamp bead through voltage or digital signals, thereby achieving precise control of RGB lights.

Further, a transparent encapsulant layer is filled in the groove 4 to make the top surface of the package body 1 flat (as shown in FIG. 14). After the transparent encapsulant layer fills the groove 4, the light-emitting unit group 5 is encapsulated and protected, resulting in a longer service life.

Since multiple chips 2 are encapsulated simultaneously in the present disclosure, a cutting process is finally required to cut the encapsulation material at the cutting path position to separate the product units (as shown in FIG. 15). Each product unit's encapsulation material as a whole forms the package body 1, and then the substrate is removed by mechanical stripping or other methods. By mounting the chip 2 in a face-up manner and then opening a groove 4 on the top surface of the encapsulation above the chip 2 to mount the light-emitting unit group 5, the electrical control of the light-emitting unit group 5 by the chip 2 is realized. The entire process is simple, the size is reduced, the cost is lowered, and the inner wall of the groove 4 formed in the encapsulation body has a reflective and converging effect on the three primary colors light of the light-emitting unit group 5. Moreover, the encapsulation material is black, which is conducive to the mixed light effect.

By adjusting the intensity of the three colors of the light-emitting unit group 5, more than 16 million different colors can be produced. When the three primary colors are mixed, the additive principle of mixed light is followed: when the spectral distribution or color coordinates of the RGB three-color light sources involved in the mixed light are determined, any color within the region can be mixed. The mixed color is determined by the relative proportion of the light flux of the RGB three primary colors, and the total brightness of the mixed light is equal to the sum of the light flux of the three primary colors, thereby realizing a very rich range of lighting effects.

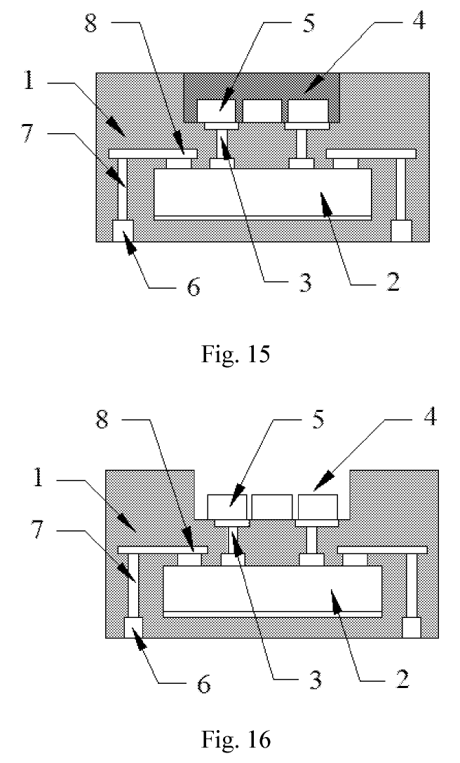

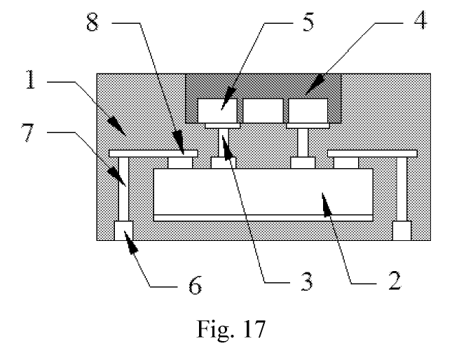

The mixed light RGB stacked structure obtained by the above packaging method of the mixed light RGB stacked structure is shown in FIGS. 16 and 17. The structure includes a package body 1, which encapsulates:

a chip 2, part of the electrodes on the front surface of the chip 2 being electrically conducted through an electroplated routing layer 8, a post 7, and a metal block 6 to the bottom surface of the package body 1, the bottom surface of the metal block 6 being flush with and exposed from the bottom surface of the package body 1;

a wire 3, the other electrodes on the front surface of the chip 2 being led out to the top surface of the package body 1 through an electroplated wire 3;

a groove 4, etched on the top surface of the package body 1 at a corresponding position, with the top surface of the wire 3 exposed within the groove 4;

a light-emitting unit group 5, mounted in the groove 4 and electrically connected to the top surface of the wire 3, thereby achieving electrical connection between the chip 2 and the light-emitting unit group 5.

After the metal block 6 is electroplated and encapsulated, its top surface is exposed by grinding. The chip 2 is mounted on the encapsulation surface and encapsulated, and then the front surface of the chip 2 is exposed by grinding. Holes are drilled in the encapsulation surface to expose the top surface of the metal block 6, a metal post 7 is electroplated in the hole, and a routing layer 8 is electroplated on the encapsulation surface. The routing layer 8 connects the post 7 and part of the electrodes on the front surface of the chip 2. The wire 3 includes metal electroplated in the hole and metal extended on the encapsulation surface, and the two parts of metal are electroplated and connected as a whole. The groove 4 is formed by laser etching and is located above the chip 2. The light-emitting unit group 5 includes red, green, and blue three primary colors lamp beads, and the lamp beads are respectively mounted at the bottom of the groove 4 and electrically connected to the wire 3 (as shown in FIG. 16).

Further, a transparent encapsulant layer is filled in the groove 4 to make the top surface of the package body 1 flat (as shown in FIG. 17). After the transparent encapsulant layer fills the groove 4, the light-emitting unit group 5 is encapsulated and protected, resulting in a longer service life.

The encapsulation material used in the present disclosure can be epoxy resin, cyanate ester, polyimide, etc., which are low in cost and have good curing performance. The encapsulation process plays an important role in the field of semiconductor manufacturing, mainly reflected in protection, connection, support, reliability, and promoting technological progress. The protective role means that the encapsulation of the chip 2 can protect it from mechanical damage, moisture, dust, and other external environmental factors, ensuring the normal operation of the chip 2 in extreme environments. The connection role means that the encapsulation provides a way to connect the chip 2 with other electronic components, enabling the chip 2 to be installed and used on the circuit board. The support role means that while supporting the chip 2, the encapsulation can also fix the chip 2 to prevent it from being damaged. Reliability means that the requirements for the reliability of encapsulation materials and processes are increasing, to ensure that the chip 2 can operate normally in various extreme environments.

All electroplating processes used in the present disclosure are first formed with electroplating protection on the surface by photolithography technology through exposure and development, and then a metal seed layer is formed in the electroplating area by sputtering or electroless plating and other suitable methods. The metal seed layer is made of copper or other metal materials. The metal seed layer is to ensure the bonding strength between the subsequently electroplated metal and the encapsulation material, while providing a surface for the attachment of conductive ions for electroplating to ensure the electroplating effect. The entire electroplating process and the materials used are common technical knowledge in this field.

The present disclosure realizes the electrical control of the light-emitting unit group 5 by the chip 2 by mounting the chip 2 in a face-up manner and then opening a groove 4 on the top surface of the encapsulation above the chip 2 to mount the light-emitting unit group 5. The entire process is simple, the size is reduced, the cost is lowered, and the inner wall of the groove 4 formed in the encapsulation body has a reflective and converging effect on the three primary colors light of the light-emitting unit group 5, achieving a good mixed light effect.

It can be understood that the present disclosure is described through some embodiments. As known to those skilled in the art, various changes or equivalent substitutions can be made to these features and embodiments without departing from the spirit and scope of the present disclosure. In addition, under the teachings of the present disclosure, these features and embodiments can be modified to adapt to specific situations and materials without departing from the spirit and scope of the present disclosure. Therefore, the present disclosure is not limited to the specific embodiments disclosed herein, and all embodiments falling within the scope of the claims of the present disclosure are protected by the present disclosure.

What is claimed is:

1. A packaging method of mixed light RGB stacked structure, comprising steps of:
chip mounting: mounting a chip on a substrate in which a metal block is encapsulated, encapsulating the chip, and grinding an encapsulation surface to expose a front surface of the chip;
electrically leading-out at a bottom side: drilling the encapsulation surface that exposes the front surface of the chip until a top surface of the metal block is exposed; extending electroplated metal in a hole and on the encapsulation surface, so that part of electrodes on the front surface of the chip are electrically conducted through the electroplated metal to the metal block and then led out to the bottom side; and encapsulating the electroplated metal;
electrically leading-out at a top side: drilling the encapsulation surface until the other electrodes on the front surface of the chip are exposed, electroplating wire to lead the other electrodes on the front surface of the chip out to the top side, and encapsulating the wire; and
light-emitting unit group mounting: etching a groove on a top of the encapsulation surface to expose a top of the wire; mounting the light-emitting unit group into the groove, and connecting the light-emitting unit group to the wire, so that the chip and the light-emitting unit group are electrically connected; stripping the substrate; and forming a package body.

2. The packaging method of mixed light RGB stacked structure according to claim 1, wherein in the step of chip mounting, the substrate is provided, the metal block is electroplated on the substrate, the metal block is set at equal height; the metal block is encapsulated on the substrate; the top of the encapsulation surface is grinded to expose the top surface of the metal block; and the chip is mounted on the encapsulation surface, a back side of the chip faces the substrate.

3. The packaging method of mixed light RGB stacked structure according to claim 1, wherein in the step of electrically leading-out at the bottom side, a metal post is electroplated in the hole, and a metal routing layer is electroplated on the encapsulation surface, wherein the routing layer connects the post and the part of electrodes on the front surface of the chip, so that the part of electrodes on the front surface of the chip are electrically conducted through the routing layer and the post to the metal block and then led out to the bottom surface.

4. The packaging method of mixed light RGB stacked structure according to claim 3, wherein in the step of electrically leading-out at the top side, the wire comprises metal electroplated in the hole and metal extended on the encapsulation surface, and two parts of metal are electroplated connected as a whole.

5. The packaging method of mixed light RGB stacked structure according to claim 1, wherein in the step of light-emitting unit group mounting, the groove is formed by laser etching and is located above the chip.

6. The packaging method of mixed light RGB stacked structure according to claim 1, wherein in the step of light-emitting unit group mounting, the light-emitting unit group comprises red, green and blue three primary colors lamp beads, the lamp beads being respectively mounted at a bottom of the groove and electrically connected to the wire.

7. The packaging method of mixed light RGB stacked structure according to claim 6, wherein in the step of light-emitting unit group mounting, a transparent encapsulant layer is filled in the groove so that a top side of the package body is flat.

8. A mixed light RGB stacked structure, comprising a package body, wherein the package body encapsulates:
a chip, part of electrodes on a front surface of the chip being electrically conducted to a bottom side of the package body through an electroplated routing layer, a post and a metal block, a bottom surface of the metal block being exposed and flush with from the bottom side of the package body;
a wire, the other electrodes on the front surface of the chip being led out to a top side of the package body through electroplated wire;
a groove, etched on the top side of the package body at a corresponding position, a top of the wire being exposed within the groove;
a light-emitting unit group, mounted in the groove and electrically connected to the top of the wire, thereby the chip and the light-emitting unit group are electrically connected.

9. The mixed light RGB stacked structure according to claim 8, wherein after the metal block is electroplated and encapsulated, their top surfaces are exposed by grinding, the chip is mounted on the encapsulation surface and encapsulated, and then the front surface of the chip is exposed by grinding.

10. The mixed light RGB stacked structure according to claim 9, wherein the encapsulation surface is drilled to expose a top surface of the metal block, a metal post is electroplated in the hole, and a routing layer is electroplated on the encapsulation surface to connect the post and the part of electrodes on the front surface of the chip.

11. The mixed light RGB stacked structure according to claim 10, wherein the wire comprises metal electroplated in the hole and metal extended on the encapsulation surface, and two parts of metal are electroplated connected as a whole.

12. The mixed light RGB stacked structure according to claim 8, wherein the groove is formed by laser etching and is located above the chip.

13. The mixed light RGB stacked structure according to claim 8, wherein the light-emitting unit group comprises red, green and blue three primary colors lamp beads, the lamp beads being respectively mounted at a bottom of the groove and electrically connected to the wire.

14. The mixed light RGB stacked structure according to claim 13, wherein a transparent encapsulant layer is filled in the groove so that a top side of the package body is flat.
